(19) United States
(12) Patent Application Publication
(10) Pub. No.: US 2012/0291864 A1
(43) Pub. Date: Nov. 22, 2012

(54) SOLAR CELL AND SOLAR CELL FABRICATION METHOD

(75) Inventors: Gyu-Bong Cho, Jinju-si (KR); Jung-Pil Noh, Masan-si (KR); Ki-Won Kim, Jinju-si (KR)

(73) Assignees: Nexcon Tec., Ltd., Chungcheongnam-Do (KR); Industry-Academic Cooperation Foundation Gyeongsang National University, Gyeongsangnam-do (KR)

(21) Appl. No.: 13/512,549

(22) PCT Filed: Nov. 30, 2009
(86) PCT No.: PCT/KR09/07089

§ 371 Date: Aug. 10, 2012

(51) Int. Cl. H01L 31/0224; H01L 31/18

(52) U.S. Cl. 136/256; 438/98; 257/E31.124

(57) ABSTRACT

A solar cell is provided. The solar cell includes a substrate which converts light energy into electric energy, a hole which penetrates through the substrate in a vertical direction, and an upper electrode which has a radial pattern with reference to the hole on a surface of the substrate.

### TECHNICAL FIELD

The present invention relates to a solar cell and a method for manufacturing a solar cell, and more particularly, to a solar cell which includes a hole penetrating therethrough and an electrode formed in a radial pattern with reference to the hole, thereby minimizing an area of the electrode formed on an upper portion of the solar cell, and a method for manufacturing a solar cell.

### DESCRIPTION OF RELATED ART

In recent years, worldwide demand for new renewable energy sources such as wind power, sunlight, fuel cells, and tidal power generation is increasing along with the development of eco-friendly energy sources, the obligation to reduce CO₂ emission, and the advent of the high oil prices era.

Among theses, a solar cell includes a solar heat cell that generates steam necessary for rotating a turbine using solar heat, and a sunlight cell that converts sunlight into electric energy using a semiconductor property. The solar cell generally refers to the sunlight cell. Hereinafter, the sunlight cell is referred as a solar cell.

Referring to FIG. 20, a solar cell has a junction structure of a P-type semiconductor and an N-type semiconductor like a diode. If light enters the solar cell, negatively charged electrons and positively charged holes are generated by interaction between the light and materials forming the semiconductor of the solar cell. The electrons and the holes are moved so that an electric current flows. This operation is called a photovoltaic effect. Among the P-type semiconductor and the N-type semiconductor of the solar cell, the electrons are attracted to the N-type semiconductor and the holes are attracted to the P-type semiconductor, so that the electrons and the holes are moved to an electrode connected with the N-type semiconductor and an electrode connected with the P-type semiconductor, respectively.

FIG. 20 is a cross section view of a related-art solar cell.

Referring to FIG. 20, a related-art solar cell includes electrodes 40 and 50 to collect electrons generated in an N-type semiconductor. However, the electrode formed in a light receiving area of the solar cell hinders light from penetrating through the solar cell, and thus efficiency of the solar cell depends on the area of the electrode formed on a surface of the solar cell.

However, in the related-art solar cell, a collector line 40 of the electrodes 40 and 50, which has a relatively large area, is formed on the surface of the solar cell, and thus, it is difficult to minimize the area occupied by the electrode on the surface of the solar cell.

### DETAILED DESCRIPTION OF THE PRESENT INVENTION

### Technical Object

The present invention has been developed in order to solve the above problems. An object of the present invention is to provide a solar cell which includes a hole penetrating therethrough and an electrode formed in a radial pattern with reference to the hole, thereby minimizing an area of the electrode formed on a surface of the solar cell, and a method for manufacturing a solar cell.

### Technical Solving Method

According to an aspect of an exemplary embodiment, there is provided a solar cell, including: a substrate which converts light energy into electric energy, a hole which penetrates through the substrate in a vertical direction, and an upper electrode which has a radial pattern with reference to the hole on a surface of the substrate.

The upper electrode may include a plurality of first electrodes of a line form which are arranged from the hole in a direction toward an edge of the substrate.

The upper electrode may further include a plurality of second electrodes which are connected to each of the plurality of first electrodes in a perpendicular direction.

The upper electrode may further include a plurality of second electrodes which are connected to the plurality of first electrodes and are formed around the hole in a circular pattern.

The second electrode may have a width narrower than a width of the first electrode.

The solar cell may further include: a lower electrode which is formed on a lower portion of the substrate, and an insulation layer which insulates a surface of the hole, and the hole may be electrically connected to the upper electrode.

The substrate may include: a first conductive silicon substrate, and a second conductive silicon substrate which has an opposite conductivity type to a conductivity type of the first conductive silicon substrate and forms a P-N junction with the first conductive silicon substrate.

The first conductive silicon substrate may be a P-type silicon substrate.

According to an aspect of another exemplary embodiment, there is provided a method for manufacturing a solar cell, the method including: preparing a substrate to convert light energy into electric energy, forming a hole through the substrate in a vertical direction, forming a lower electrode on a lower portion of the substrate, forming an insulation layer to insulate a surface of the hole, and forming an upper electrode on an upper surface of the substrate in a radial pattern with reference to the hole.

The forming the upper electrode may include forming the upper electrode in a screen printing method.

The forming the upper electrode may include forming the upper electrode so that the upper electrode comprises a plurality of first electrodes which are arranged from the hole in a direction toward an edge of the substrate.

The forming the upper electrode may include forming the upper electrode so that the upper electrode further comprise a plurality of second electrodes which are connected to each of the plurality of first electrodes in a perpendicular direction.

The forming the upper electrode may include forming the upper electrode so that the upper electrode further comprises a plurality of second electrodes which are connected to the plurality of first electrodes and are formed from the hole in a circular pattern.

The forming the upper electrode may include forming the upper electrode so that the second electrode has a width narrower than a width of the first electrode.

The preparing the substrate may include preparing a first conductive silicon substrate and a second conductive silicon substrate forming a P-N junction.

### Advantageous Effect

Since the solar cell and the method for manufacturing the solar cell according to the exemplary embodiments have the upper electrode of the radial pattern, an area of a collector line having a relatively wide width can be reduced and thus an area occupied by the electrode in a light receiving area of the solar cell can be minimized.

Also, since the solar cell and the method for manufacturing the solar cell according to the exemplary embodiments output electric charge collected in the upper electrode to the lower portion of the solar cell through the hole, it is not necessary to form a solder to output power on the light receiving area of the solar cell, and thus the area occupied by the electrode in the light receiving area can be further reduced.

### BRIEF DESCRIPTION OF THE DRAWINGS

FIG. 1 is a view illustrating a solar cell according to an exemplary embodiment;

FIGS. 2 to 8 are cross section views to explain a process of manufacturing a solar cell according to an exemplary embodiment;

FIGS. 9 to 15 are side views to explain a process of manufacturing a solar cell according to an exemplary embodiment;

FIGS. 16 to 18 are views illustrating various patterns of an upper electrode of a solar cell according to an exemplary embodiment;

FIG. 19 is a flowchart illustrating a process of manufacturing a solar cell according to an exemplary embodiment; and

FIG. 20 is a view illustrating a related-art solar cell.

### DESCRIPTION OF THE REFERENCE NUMERALS IN THE DRAWINGS

| | |
|---|---|
| 100: solar cell | 110: first conductive silicon |
| | substrate |
| 120: second conductive silicon substrate | 130: hole |
| 140: upper electrode | 150: lower electrode |
| 160: insulation layer | |

### BEST MODE FOR EMBODYING THE INVENTION

Hereinafter, the present invention will now be described in greater detail with reference to the accompanying drawings.

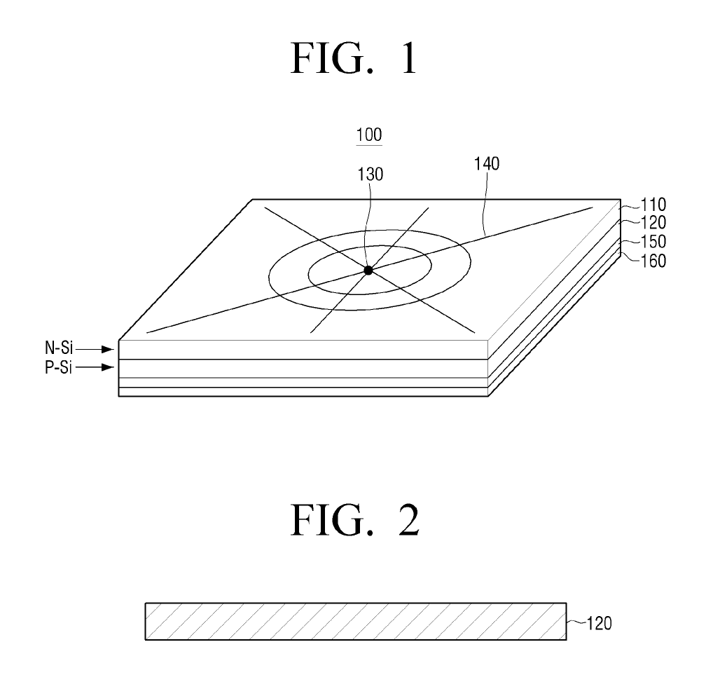

FIG. 1 is a view illustrating a solar cell according to an exemplary embodiment.

Referring to FIG. 1, a solar cell 100 according to an exemplary embodiment includes substrates 110 and 120, a hole 130, an upper electrode 140, a lower electrode 150, and an insulation layer 160.

The substrates 110 and 120 convert light energy into electric energy. Specifically, the substrates 110 and 120 may be substrates that are used in a single crystalline silicon solar cell, a poly crystalline silicon solar cell, an amorphous silicon solar cell, a compound solar cell, and a dye-sensitized solar cell. Hereinafter, a silicon substrate forming a P-N junction will be explained, but, it should be understood that the substrate of the present invention is not limited to the silicon substrate forming the P-N junction.

Specifically, the substrates 110 and 120 may be realized by a first conductive silicon substrate 110 and a second conductive silicon substrate 120. The first conductive silicon substrate 110 and the second conductive silicon substrate 120 are silicon substrates having different conductivity types. Specifically, if the first conductive silicon substrate 110 is an N-type silicon substrate, the second conductive silicon substrate 120 may be a P-type silicon substrate. On the contrary, if the first conductive silicon substrate 100 is a P-type silicon substrate, the second conductive silicon substrate 120 may be an N-type silicon substrate.

The first conductive silicon substrate 110 and the second conductive silicon substrate 120 form a P-N junction. Specifically, if the second conductive silicon substrate 120 is a P-type silicon substrate, an N-type conductive layer is formed by doping a top of the second conductive silicon substrate 120 with a group-V element such as P, As, and Sb, so that the first conductive silicon substrate 110 and the second conductive silicon substrate 120 have a P-N junction. In practice, a silicon substrate having a P-N junction may be formed by stacking an N-type silicon substrate on a P-type silicon substrate and heating the N-type silicon substrate and the P-type silicon substrate. Although only the silicon substrate forming the P-N junction is explained in the present exemplary embodiment, a silicon substrate forming a P-I-N junction and a different substrate as described above may be used in practice.

The hole 130 penetrates through the substrates 110 and 120 in a vertical direction. Specifically, the hole 130 vertically penetrating through the first conductive silicon substrate 110 and the second conductive silicon substrate 120 may be formed by processing the first conductive silicon substrate 110 and the second conductive silicon substrate 120 forming the P-N junction using a laser method, an etching method, or a mechanical punching method.

The hole 130 may include a conductive material 180. Specifically, the hole 130 has a surface insulated through the insulation layer 160 and the conductive material 180 is filled in the insulated hole 130. The conductive material 180 may be electrically connected to the upper electrode 140. Accordingly, the solar cell 100 may output power generated by the solar cell 100 through a lower portion of the solar cell 100.

The upper electrode 140 is formed on a surface of the substrates 110 and 120 in a radial pattern with reference to the hole. Specifically, the upper electrode 140 may include a plurality of first electrodes of a line form which are arranged from the hole 130 in a direction toward an edge of the first conductive silicon substrate 110. The upper electrode 140 may include the plurality of first electrodes and a plurality of second electrodes which are connected to each of the plurality of first electrodes in a perpendicular direction. The upper electrode 140 may include the plurality of first electrodes and a plurality of second electrodes which are formed around the hole in a circular pattern. The various patterns of the upper electrode 140 will be explained below with reference to FIGS. 16 to 18.

The lower electrode 150 is formed on a lower portion of the substrates 110 and 120. Specifically, the lower electrode 150 is formed on a surface of the second conductive silicon substrate 120.

The insulation layer 160 insulates a surface of the hole 130. Specifically, the insulation layer 160 may insulate between the lower electrode 150 and the upper electrode 140 and the conductive material 180. In practice, the insulation layer 160 may insulate not only the surface of the hole 130 but also an upper portion of the lower electrode 150, as shown in FIG. 1.

Since the solar cell 100 according to the present exemplary embodiment has the upper electrode of the radial pattern as described above, an area of a collector line having a relatively wide width can be reduced and thus an area occupied by the electrode in a light receiving area of the solar cell can be minimized.

Also, since the solar cell 100 according to the present exemplary embodiment outputs electric charge collected in the upper electrode 140 to the lower portion of the solar cell 100 through the hole 130, it is not necessary to form a solder to output power on the light receiving area of the solar cell 100, and thus the area occupied by the electrode in the light receiving area can be further reduced.

FIGS. 2 to 15 are views to explain a process of manufacturing a solar cell according to an exemplary embodiment. Hereinafter, a process of manufacturing a solar cell will be explained with reference to FIGS. 2 to 15. The process of manufacturing the solar cell according to the exemplary embodiment will be explained using a silicon substrate forming a P-N junction from among substrates to which the present invention is applicable. However, it should be understood that the following process may be modified using other substrates than the silicon substrate forming the P-N junction as described.

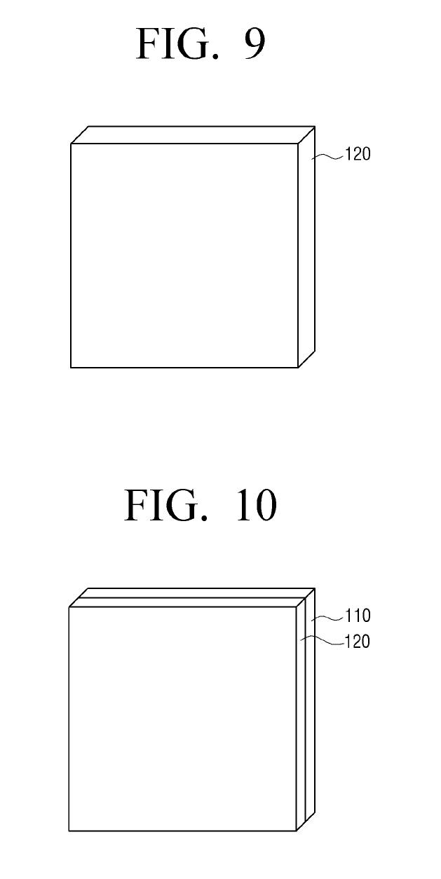

Referring to FIGS. 2 and 9, a second conductive silicon substrate 120 is prepared first. The second conductive silicon substrate 120 may use both P-type and N-type silicon substrates. Since the P-type silicon substrate is advantageous to the lifespan of a minority carrier and has great mobility, it is preferable to use the P-type silicon substrate. Therefore, hereinafter, the process will be explained on the assumption that the second conductive silicon substrate 120 is a P-type silicon substrate.

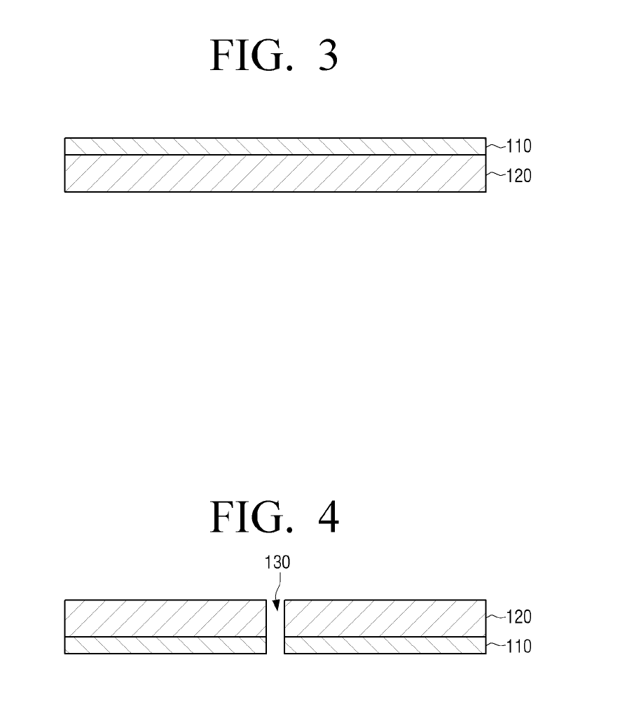

Next, silicon substrates 110 and 120 having a P-N junction are formed as shown in FIGS. 3 and 10. Specifically, since the P-type silicon substrate is doped with group-III elements such as B, Ga, and In, a top of the second conductive silicon substrate 120 is doped with a group-V element such as P, As, Sb, so that the first conductive silicon substrate 110 and the second conductive silicon substrate 120 having the P-N junction can be formed.

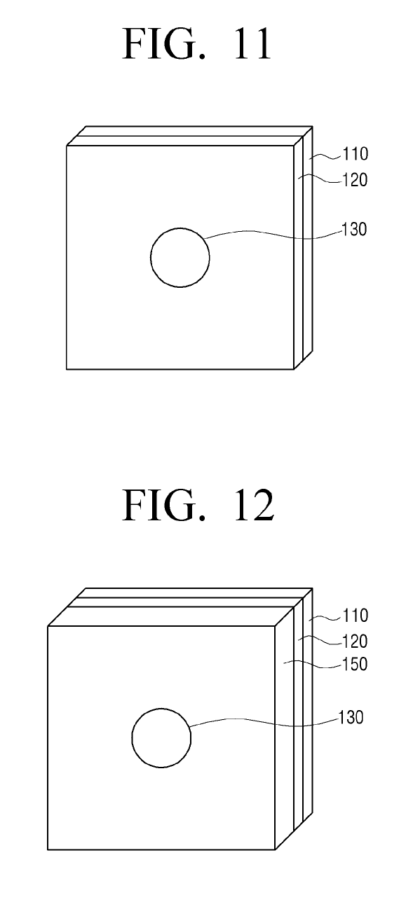

Next, a hole is formed through the first conductive silicon substrate 110 and the second conductive silicon substrate 120 forming the P-N junction as shown in FIGS. 4 and 11. Specifically, the hole 130 may be formed through the first conductive silicon substrate 110 and the second conductive silicon substrate 120 in a vertical direction using a laser method, an etching method, and a mechanical punching method.

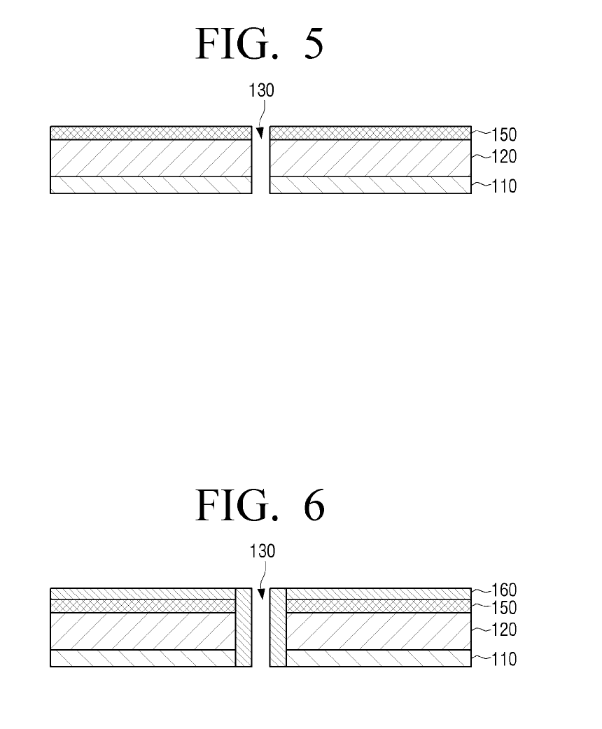

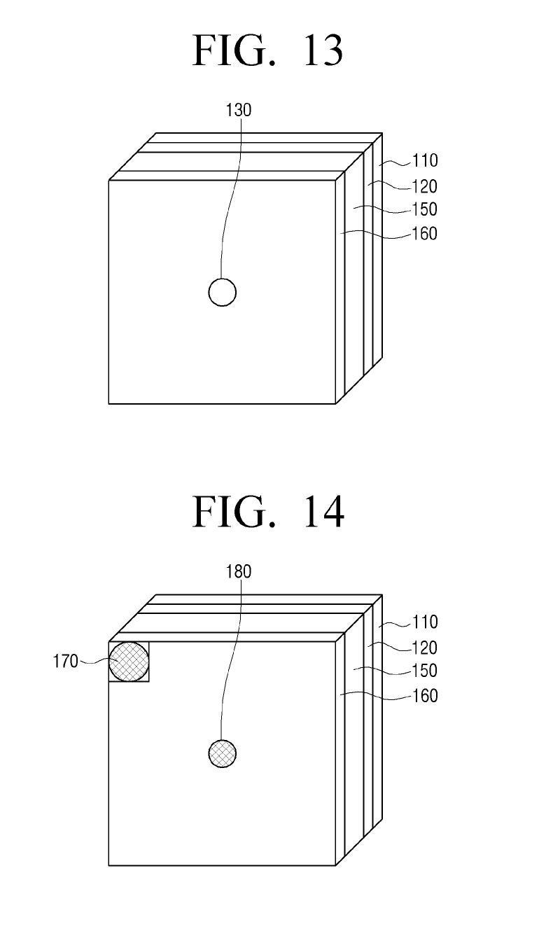

Next, a lower electrode 150 is formed on a surface of the second conductive silicon substrate 120 as shown in FIGS. 5 and 12. Specifically, the lower electrode 150 may be formed on the surface of the second conductive silicon substrate 120 using a thin film processing method, a coating method, a sputtering method, a plating method, or a printing method.

Next, an insulation layer 160 is formed on a surface of the hole 130 as shown in FIGS. 6 and 13. Specifically, the insulation layer 160 may be formed on the surface of the hole 130 using polymer, oxide, or nitride. At this time, the insulation layer 160 may be formed on not only the surface of the hole 130 but also an upper area of the lower electrode 150.

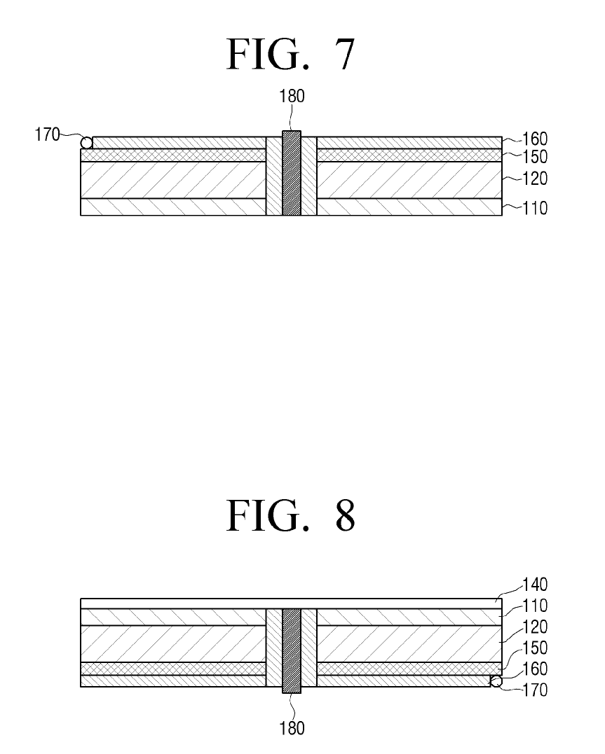

Next, a conductive material 180 and a solder 170 are formed as shown in FIGS. 7 and 14. Specifically, the conductive material 180 may be filled in the hole 130 and the solder 170 may be formed on one side surface of the lower electrode 150 to output power of the solar cell 100 using a thin film processing method, a coating method, a sputtering method, or a plating method.

In practice, a reflection prevention film may be formed on an upper portion of the first conductive silicon substrate 110 before an upper electrode 140 is formed.

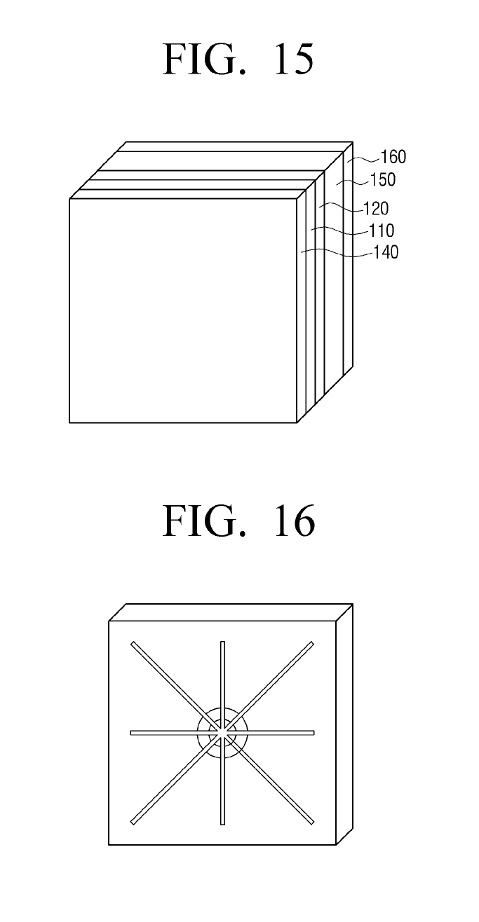

Next, the upper electrode 140 is formed on an upper surface of the substrates 110 and 120 as shown in FIGS. 8 and 15. Specifically, the upper electrode 140 may be formed on the upper portion of the first conductive silicon substrate 110 in a radial pattern with reference to the hole using a screen printing method.

In practice, the upper electrode 140 may be formed by etching the upper surface of the substrates 110 and 120 in the pattern shown in FIG. 1 and FIGS. 16 to 18 and performing electric plating or sputtering with respect to the etched surface.

The electrode 140 may have various radial patterns and examples thereof will be explained with reference to FIGS. 16 to 18.

FIGS. 16 to 18 are views illustrating various patterns of the upper electrode of the solar cell according to an exemplary embodiment.

Referring to FIG. 16, the upper electrode 140 includes a plurality of first electrodes of a line form which are arranged from the hole 130 in a direction toward an edge of the substrates 110 and 120. In the example illustrated in the drawing, the upper electrode 140 includes four conductive lines, but the upper electrode 140 may be realized using more than four conductive lines.

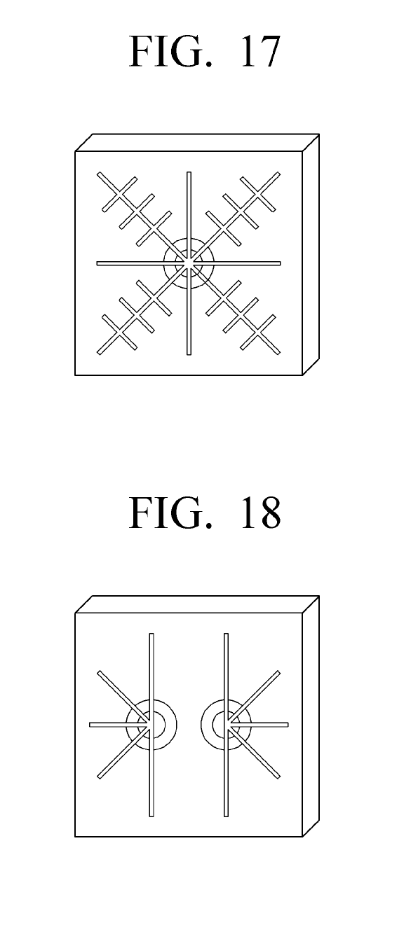

Referring to FIG. 17, the upper electrode 140 may include a plurality of first electrodes of a line form which are arranged from the hole 130 in the direction toward the edge of the substrates 110 and 120, and a plurality of second electrodes which are connected to each of the plurality of conductive lines in a perpendicular direction. In the example shown in the drawing, the plurality of second electrodes have the same length, but, the plurality of second electrodes may have different lengths in proportion to a distance from the hole.

The plurality of second electrodes may have a pattern shown in FIG. 1. Specifically, the plurality of second electrodes are connected to the plurality of first electrodes and are arranged around the hole in a circular pattern.

In practice, a width of the second electrode may be made narrower than that of the first electrode, so that the electrode area of the upper electrode 140 can be further reduced.

Referring to FIG. 18, the solar cell 100 may include two holes 130 and the upper electrode 140 may have a radial pattern with reference to each of the holes. The two holes shown in FIG. 18 may be smaller than the holes shown in FIGS. 16 and 17.

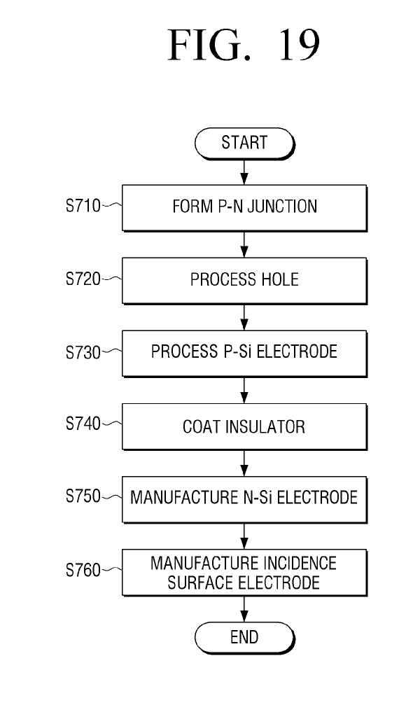

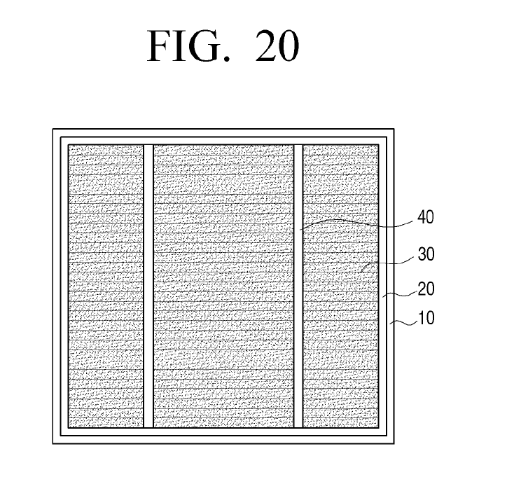

FIG. 19 is a flowchart illustrating a process of manufacturing a solar cell according to an exemplary embodiment.

First, a substrate to convert light energy into electric energy is prepared (S710). Specifically, a first conductive silicon substrate and a second conductive silicon substrate forming a P-N junction may be prepared. In practice, a silicon substrate forming a P-N junction may be formed by stacking an N-type silicon substrate on a P-type silicon substrate and heating the N-type silicon substrate and the P-type silicon substrate, and an amorphous silicon substrate, a compound substrate, and a dye-sensitized substrate forming a P-I-N junction may be prepared.

Next, a hole is formed through the substrate (S720). Specifically, a hole may be vertically formed through the substrate using a laser method or a mechanical punching method.

Next, a lower electrode is formed on a lower portion of the substrate (S730). Specifically, a lower electrode may be formed on the lower portion of the substrate using a thin film processing method, a coating method, a spin coating method, a plating method, or a printing method.

Next, an insulation layer is formed to insulate a surface of the hole (S740). Specifically, an insulation layer may be formed to insulate the surface of the hole using polymer, oxide, or nitride. At this time, an insulation layer may be formed to insulate a surface of the lower electrode 150.

Next, a conductive material is filled in the hole and a solder for the lower electrode is formed (S750). Specifically, the hole is filled using various conductive materials and a solder may be formed on a predetermined area of the lower electrode to output power of the solar cell 100.

Next, an upper electrode is formed on an upper portion of the substrate in a radial pattern with reference to the hole (S760). Specifically, the upper surface of the substrate may be processed by screen printing or etching and plating so that the upper electrode is formed as shown in FIG. 1 and FIGS. 16 to 18. In practice, a reflection prevention film may be formed on the upper surface of the substrate before the upper electrode is formed, and then the upper electrode may be formed.

Although various example embodiments of the present general inventive concept have been illustrated and described, it will be appreciated by those skilled in the art that changes may be made in these example embodiments without departing from the principles and spirit of the general inventive concept, the scope of which is defined in the appended claims and their equivalents.

1. A solar cell comprising:
a substrate which converts light energy into electric energy;
a hole which penetrates through the substrate in a vertical direction; and
an upper electrode which has a radial pattern with reference to the hole on a surface of the substrate.

2. The solar cell as claimed in claim 1, wherein the upper electrode comprises a plurality of first electrodes of a line form which are arranged from the hole in a direction toward an edge of the substrate.

3. The solar cell as claimed in claim 2, wherein the upper electrode further comprises a plurality of second electrodes which are connected to each of the plurality of first electrodes in a perpendicular direction.

4. The solar cell as claimed in claim 2, wherein the upper electrode further comprises a plurality of second electrodes which are connected to the plurality of first electrodes and are formed around the hole in a circular pattern.

5. The solar cell as claimed in claim 3 or 4, wherein the second electrode has a width narrower than a width of the first electrode.

6. The solar cell as claimed in claim 1, further comprising:
a lower electrode which is formed on a lower portion of the substrate; and
an insulation layer which insulates a surface of the hole,
wherein the hole is electrically connected to the upper electrode.

7. The solar cell as claimed in claim 1, wherein the substrate comprises:
a first conductive silicon substrate; and
a second conductive silicon substrate which has an opposite conductivity type to a conductivity type of the first conductive silicon substrate and forms a P-N junction with the first conductive silicon substrate.

8. The solar cell as claimed in claim 7, wherein the first conductive silicon substrate is a P-type silicon substrate.

9. A method for manufacturing a solar cell, the method comprising:
preparing a substrate to convert light energy into electric energy;
forming a hole through the substrate in a vertical direction;
forming a lower electrode on a lower portion of the substrate;
forming an insulation layer to insulate a surface of the hole; and
forming an upper electrode on an upper surface of the substrate in a radial pattern with reference to the hole.

10. The method as claimed in claim 9, wherein the forming the upper electrode comprises forming the upper electrode in a screen printing method.

11. The method as claimed in claim 9, wherein the forming the upper electrode comprises forming the upper electrode so that the upper electrode comprises a plurality of first electrodes which are arranged from the hole in a direction toward an edge of the substrate.

12. The method as claimed in claim 11, wherein the forming the upper electrode comprises forming the upper electrode so that the upper electrode further comprise a plurality of second electrodes which are connected to each of the plurality of first electrodes in a perpendicular direction.

13. The method as claimed in claim 11, wherein the forming the upper electrode comprises forming the upper electrode so that the upper electrode further comprises a plurality of second electrodes which are connected to the plurality of first electrodes and are formed from the hole in a circular pattern.

14. The method as claimed in claim 12 or 13, wherein the forming the upper electrode comprises forming the upper electrode so that the second electrode has a width narrower than a width of the first electrode.

15. The method as claimed in claim 9, wherein the preparing the substrate comprises preparing a first conductive silicon substrate and a second conductive silicon substrate forming a P-N junction.
